(19) United States
(12) Patent Application Publication
(10) Pub. No.: US 2008/0089129 A1
(43) Pub. Date: Apr. 17, 2008

(54) Flash memory device with flexible address mapping scheme

(76) Inventor: Jong-Soo Lee, Seocho-gu (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/730,511

(22) Filed: Apr. 2, 2007

(30) Foreign Application Priority Data
Oct. 16, 2006 (KR) 2006-100428

(51) Int. Cl. G11C 16/02

(52) U.S. Cl. 365/185.17; 365/185.33

(57) ABSTRACT

A flash memory device includes a flash memory cell array which includes a plurality of memory cells arranged in rows and columns, reading and programming circuitry configured to read data from and program data into the memory cells of the flash memory cell array, and a control logic block configured to regulate the reading and programming circuitry in accordance with a selected one of plural address coding schemes.

### BACKGROUND OF THE INVENTION

1. Field of the Invention

The present disclosure relates generally to semiconductor memory devices and, more particularly, to flash memory devices.

A claim of priority under 35 U.S.C. § 119 is made to Korean Patent Application No. 2006-100428 filed on Oct. 16, 2006, the entire contents of which are hereby incorporated by reference.

2. Discussion of Related Art

A single-bit flash memory device is capable of storing one bit per memory cell, while a multi-bit flash memory device is capable of storing two or more bits per cell. Referring to FIG. 1, a single-bit flash memory device (SLC) stores 1-bit data per cell by programming each memory cell into one of two threshold voltage (Vth) states ST0 and ST1. In contrast, for example, a multi-bit flash memory device (MLC) stores 2-bit data per cell by programming each memory cell into one of four threshold voltage states ST0, ST1, ST2, and ST3. In the case where a multi-bit flash memory device stores 2-bit data per cell, two addresses to each memory cell, i.e., one address for is allocated each data bit.

Addresses provided to a semiconductor memory device are basically differentiated into row and column addresses. To this end, different schemes may be used to allocate row addresses and column addresses. Specifically, referring collectively to FIGS. 2 through 4, a scheme may be used to allocate a row address (hereinafter, referred to as ‘row address coding scheme’) and another scheme may be used to allocate a column address (hereinafter, referred to as ‘column address coding scheme’). Conventionally, only one of the two coding schemes is usable in a flash memory device to the exclusion of the other.

The row address coding scheme allocates two page/row addresses to a unit memory cell that includes 2-bit data. Similarly, the column address coding scheme allocates two column addresses to a unit memory cell including 2-bit data. The column and row address coding schemes have different features which will now be described in detail.

In a row address coding scheme, it is possible to conduct reading and programming operations separately and independently for each page address. Thus, in a 2-bit cell, the time taken to read/program the data from/in the cell may be equal to the sum of the times taken to read/program each individual bit. On the other hand, in a memory cell using a column address coding scheme, 2-bit reading and programming operations may be conducted on a memory cell at the same time.

Therefore, because the row address coding scheme operates to separately drive two addresses, the time taken to process data in a memory cell may increase. This is because a time for processing one address may be shorter than a time for processing two addresses. Furthermore, when there is a bit error in a memory cell, the row address coding scheme may generate a single bit error on a page. On the other hand, the column address coding scheme generates two error bits on a page. Therefore, a current error check and correction (ECC) process for repairing a 1-bit error is usually carried out in the row address coding scheme.

Yet, some features of a row address coding scheme may not be suitable for highly integrated semiconductor devices. This is because various efforts are made to reduce coupling effects between floating gates in highly integrated semiconductor devices which may lead to an increase in the number of programming operations for a multi-bit memory device. For example, in a multi-bit flash memory device, the most significant bit (MSB) data is stored by performing programming operations three times in a row in order to reduce the above-mentioned coupling effects. This increase in the number of programming operations coupled with the large time taken to program two addresses in each programming operation of a memory cell using a row address coding scheme may make the choice of a row address coding scheme less desirable.

Furthermore, there is a large time period between programming the LSB and the MSB of a memory cell using the row address coding scheme. However, the row address coding scheme is able to correct a 1-bit error and is also able to offset coupling effects between floating gates by the LSB programming operation while programming MSB data.

On the other hand, in memory devices using the column address coding scheme, a 2-bit error correction is required whenever there is a single bit failure in the cell. In addition, a programming operation is also carried out three times; and the memory device needs an additional shadow programming operation for reducing the floating-gate coupling effects. However, unlike the row address coding scheme, there is no time gap between LSB and MSB programming times in a column address coding scheme. Furthermore, the column address coding scheme is able to offer a time margin for the additional shadow programming operation. This availability of a time margin in the column address coding scheme may allow for a nearly faultless shadow programming operation.

### SUMMARY OF THE INVENTION

According to one aspect of the present disclosure, a flash memory device is provided which includes a flash memory cell array which includes a plurality of memory cells arranged in rows and columns, reading and programming circuitry configured to read data from and program data into the memory cells of the flash memory cell array, and a control logic block configured to regulate the reading and programming circuitry in accordance with a selected one of plural address coding schemes.

According to another aspect of the present disclosure, a flash memory device is provided which includes a flash memory cell array including a plurality of memory cells, each of memory cells storing N-bit data, where N is an integer of 2 or more, reading and programming circuitry configured to read data from and program data into the memory cells of the flash memory cell array, a mode register configured to store information for selecting one of plural address coding schemes, and to generate a flag signal in accordance with the stored information, and a control logic block configured to regulate the reading and programming circuitry in accordance with in response to the flag signal.

According to still another aspect of the present disclosure, a method for operating a flash memory device is provided, where the flash memory device includes a flash memory cell array of memory cells arranged in rows and columns. The method includes selecting one of plural address coding schemes which are operatively available in the flash memory device, and conducting reading and programming operations in the memory cell array in accordance with the selected address coding scheme.

### BRIEF DESCRIPTION OF THE FIGURES

Non-limiting and non-exhaustive embodiments of the present invention will be described with reference to the following figures, wherein like reference numerals refer to like parts throughout the various figures unless otherwise specified. In the figures:

FIG. 1 is a diagram showing exemplary distribution profiles of threshold voltages in single-bit and 2-bit cells;

FIG. 2 is a diagram for use in explaining row and column address coding schemes;

FIG. 3 is a diagram showing variations of threshold-voltage distribution profiles during a programming operation in accordance with a row address coding scheme;

FIG. 4 is a diagram showing variations of threshold-voltage distribution profiles during a programming operation in accordance with a column address coding scheme;

FIG. 5 is a diagram for use in explaining an address coding scheme operable in a multi-bit flash memory device according to an exemplary disclosed embodiment;

FIG. 6 is a block diagram illustrating a multi-block flash memory device according to an exemplary disclosed embodiment;

FIG. 7 is a circuit diagram illustrating the memory block shown in FIG. 6; and

FIG. 8 is a block diagram schematically illustrating a system including the multi-bit flash memory device according to an exemplary disclosed embodiment.

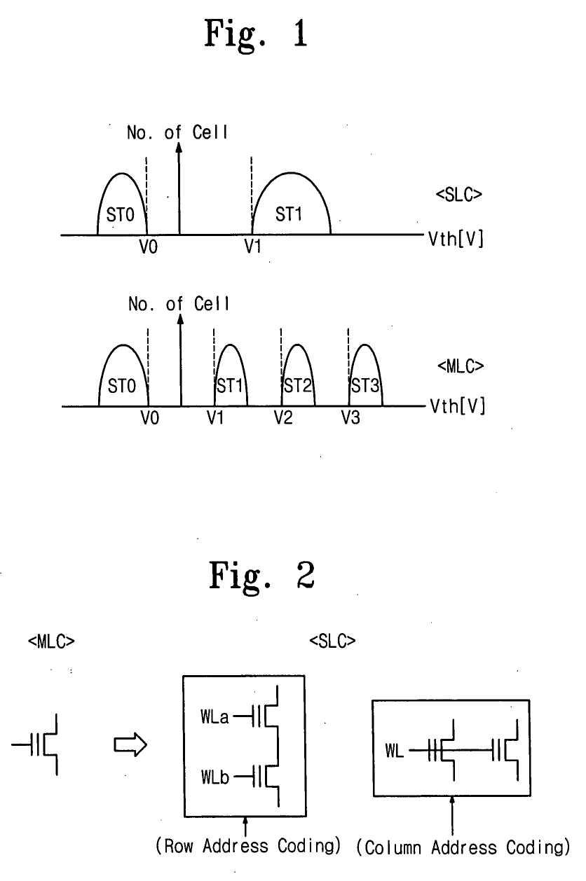

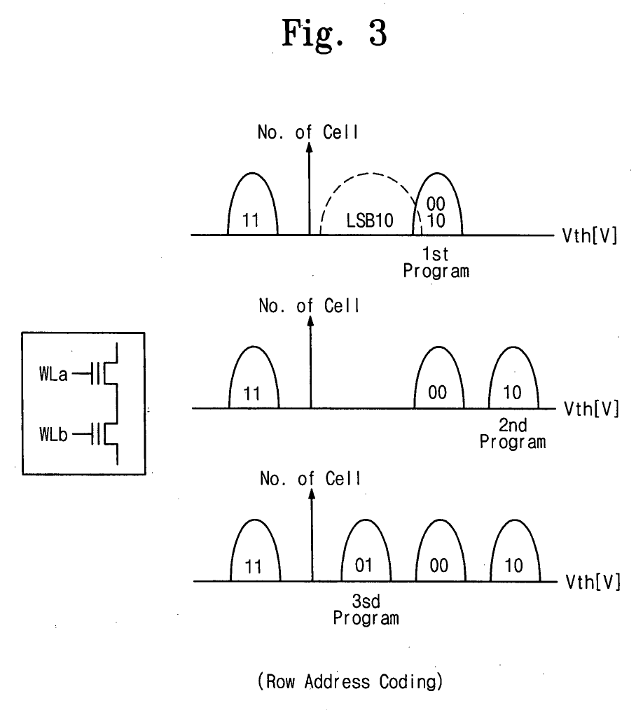

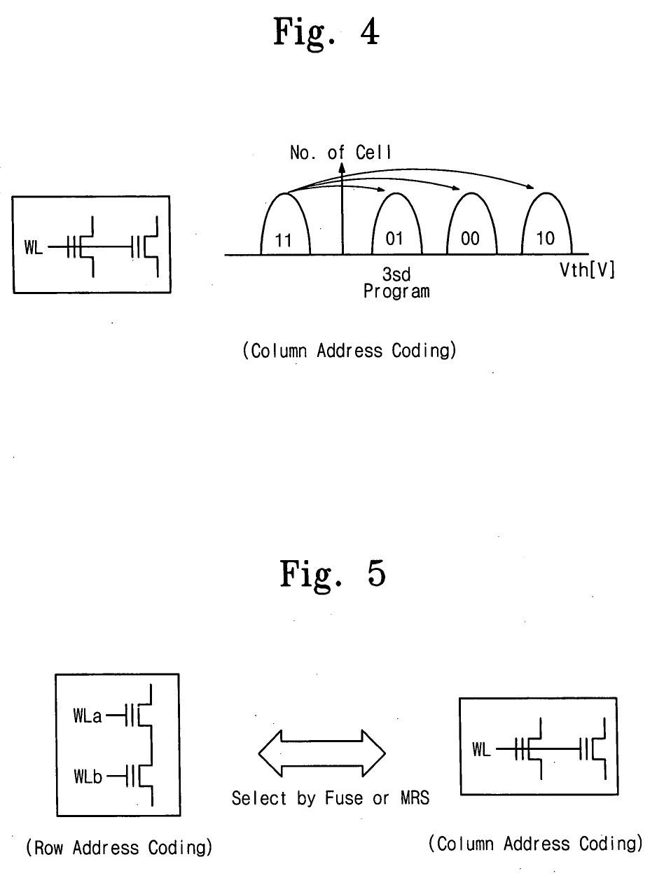

### DETAILED DESCRIPTION OF PREFERRED EMBODIMENTS

Exemplary embodiments of the present invention will be described below in more detail with reference to the accompanying drawings, showing a flash memory device as an example for illustrating structural and operational features of the invention. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout the accompanying figures.

A flash memory device according to an exemplary disclosed embodiment, as illustrated in FIG. 5, is configured to alternatively use row and column address coding schemes. Furthermore, selecting an alternative one of the row and column address coding schemes may be carried out in accordance with various operational conditions. For example, an exemplary disclosed flash memory is configured to select an alternative one of the row and column address coding schemes in accordance with the number of error bits repairable by an ECC operation, a page size, and an input/output bit organization such as x8 or x16, etc., that are provided by a memory system. In addition, the selection of the coding schemes may be carried out using various mechanisms. For example, an option circuit such as a fuse can be used for selecting the address coding scheme. Alternatively, a mode register may also be used to select the address coding scheme.

Once the coding scheme is selected by the option circuit or the mode register, reading and programming operations for a multi-bit flash memory device may be carried out according to well known procedures. To this end, exemplary reading and programming operations based on the row and column address coding schemes are disclosed in U.S. Pat. No. 6,671,204 entitled ‘Nonvolatile memory device with page buffer having dual registers and methods of using the same’, and U.S. Pat. No. 6,411,551 entitled ‘Multi-state nonvolatile semiconductor memory device which is capable of regularly maintaining a margin between threshold voltage distributions’, all of which are incorporated herein by reference.

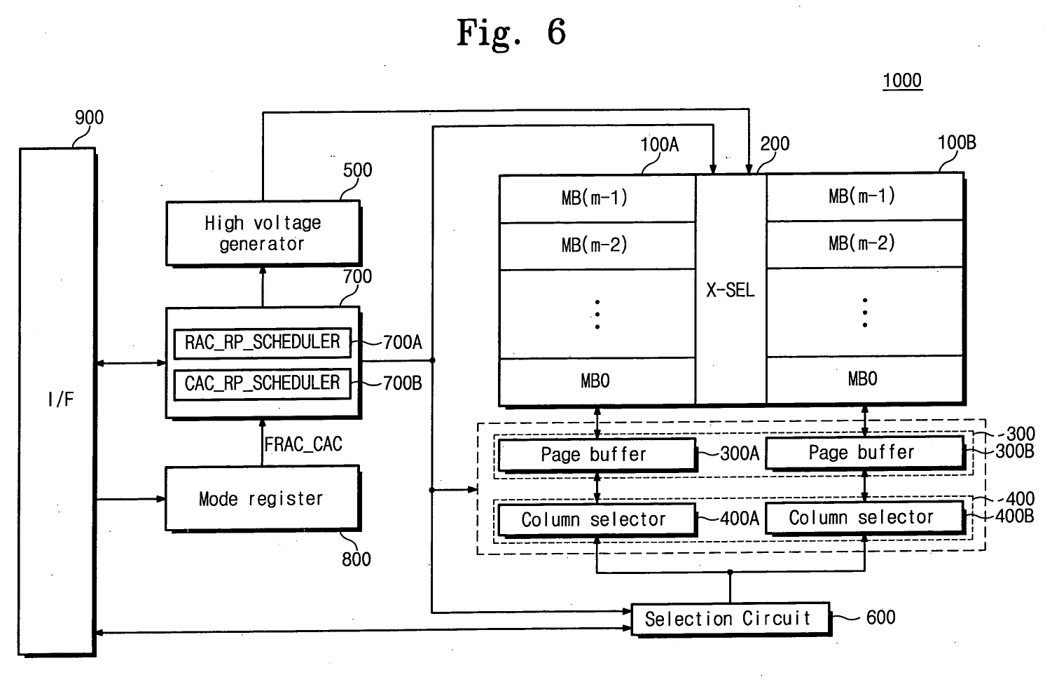

FIG. 6 is a block diagram illustrating a multi-block flash memory device 1000 according to an exemplary disclosed embodiment. Referring to FIG. 6, the multi-bit flash memory device 1000 includes a memory cell array storing multi-bit data such as, for example, 2-bit data. This memory cell array is composed of two mats 100A and 100B. Each mat includes pluralities of memory blocks MB0˜MBm−1, each of which is formed of memory cells arranged on rows and columns. Furthermore, the memory cells included in each memory block are configured in a NAND string structure.

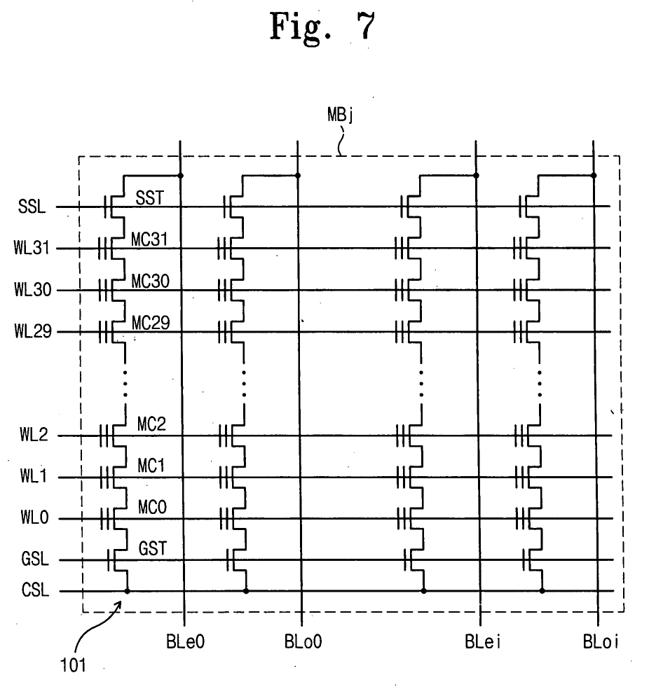

FIG. 7 is a circuit diagram illustrating a NAND string 101 according to an exemplary disclosed embodiment. The NAND string 101, as shown in FIG. 7, includes a string selection transistor SST, a ground selection transistor GST, and memory cells MC31˜MC0. Moreover, each memory cell is includes a floating gate transistor. The string selection transistor SST is controlled by a string selection line SSL and connected to a corresponding bit line through its drain. Furthermore, the ground selection transistor GST is controlled by a ground selection line GSL and connected to a common source line CSL through its source. The memory cells MC31˜MC0 are serially connected between a source of the string selection transistor SST and a drain of the ground selection transistor GST, being controlled by word lines corresponding each thereto. In addition, a plurality of bit line pairs BLe0/BLo0˜BLei/BLoi are arranged to intersect word lines WL31˜WL0. During a reading or programming operation, one of the bit line pairs is selected by a page buffer circuit shown in FIG. 6.

As illustrated in FIG. 6, the multi-bit flash memory device 1000 includes a row selector (X-SEL) 200, a page buffer block 300, a column selection block 400, a high voltage generator 500, a selection circuit 600, a control logic block 700, a mode register 800, and an interface (I/F) block 900.

The row selector 200 is regulated by the control logic block 700 and configured to select one or all of the mats 100A and 100B in accordance with operation mode. The page buffer block 300 includes page buffer circuits 300A and 300B corresponding each to the mats 100A and 100B. Each page buffer circuit may be properly formatted to read and program data of one page while being regulated by the control logic block 700.

During a reading operation in the row address coding scheme, each page buffer circuit detects 1-page data while being regulated by the control logic block 700. In contrast, during a reading operation in the column address coding scheme, each page buffer circuit detects 2-page data from its corresponding mat while being regulated by the control logic block 700. Furthermore, the column selection block 400 includes column selectors 400A and 400B corresponding to the mats 100A and 100B or the page buffer circuits 300A and 300B, respectively. Each column selector is regulated by the control logic block 700 and configured to select data, which is sensed by the page buffer circuit, in a predetermined input/output bit unit (e.g., x8 or x16). For example, data selected by the column selection block 400 is output to an external system through the selection circuit 600 and the interface block 900. Moreover, the selection circuit 600 operates to select the column selectors 400A and 400B under regulation by the control logic block 700.

Examples of programming, reading, and erasing operations in a flash memory device with a mat architecture are disclosed in U.S. Pat. No. 6,735,116 entitled ‘NAND-type flash memory device with multi-page program, multi-page read, multi-block erase operations’, which is incorporated herein by reference.

Continuing with FIG. 6, the high voltage generator 500 is regulated by the control logic block 700 and configured to generate various levels of word line voltages in accordance with an operation mode. Furthermore, the high voltage generator 500 is configured to generate a voltage to be supplied into a bulk (e.g., a pocket P-well) including the mats 100A and 100B.

The control logic block 700 is configured to regulate an overall operation of the multi-bit flash memory device 1000. To this end, in an exemplary embodiment, the control logic block 700 includes first and second schedulers 700A and 700B. The scheduler 700A controls reading and programming operations according to the row address coding scheme, while the scheduler 700B controls reading and programming operations according to the column address coding scheme. The mode register 800 stores selection information provided from an external system (e.g., memory controller). Furthermore, the mode register 800 may be also configured to employ a fuse circuit for storing the selection information. In addition, the mode register 800 provides a flag signal FRAC_CRC to the control logic block 700 in accordance with the selection information. The flag signal FRAC_CRC is used for activating an alternative one of the first and second schedulers 700A and 700B. In addition, the reading and programming operations in the multi-bit flash memory device 100 may be carried out under regulation by the selected scheduler.

In an exemplary embodiment, the row selector 200, the page buffer block 300, the column selection block 400, and the selection circuit 600 constitute reading/programming circuitry for conducting the reading and programming operations to the memory cell array 100.

As described above, the multi-bit flash memory device 1000 may be configured to select one of the row and column address coding schemes. Therefore, in the multi-bit flash memory device 1000, the reading and programming operations may be carried out in accordance with the selected address coding scheme under regulation by the selected scheduler. Furthermore, it is possible to flexibly select the address coding scheme of the multi-bit flash memory device based on the operational conditions (e.g., the number of error bits repairable by ECC operation, input/output bit architecture, page size, and so on) of the flash memory device 1000.

In the multi-bit flash memory device 1000 shown in FIG. 6, it is assumed that each of the mats 100A and 100B has a page size of 1 KB. With this assumption, if the row address coding scheme is selected, the two mats 100A and 100B are both selected in order to assist the x8 input/output mode with 2 KB. In this case, page data of 1 KB read by one page buffer circuit (e.g., 300A) is output in the input/output unit of x8 and another page data of 1 KB read by the other page buffer circuit (e.g., 300B) is output in the input/output unit of x8. Thereby, it is possible to assist the x8 input/output mode of 2 KB in the multi-bit flash memory device.

In contrast, when the column address coding scheme is selected, only one of the two mats 100A and 100B is selected in order to assist the x8 input/output mode with 2 KB. This is because the column address coding scheme operates to read 2-bit data from a unit memory cell. Thus, it is able to assist the x8 input/output mode with 2 KB by outputting the page data of 2 KB, which are is read by only one page buffer circuit (e.g., 300A or 300B), in the input/output unit of x8.

Furthermore, when the column address coding scheme is selected, the two mats 100A and 100B may be both selected in order to assist the x16 input/output mode with 2 KB. In this case, page data of 2 KB read by one page buffer circuit (e.g., 300A) is output in the input/output unit of x16 and another page data of 2 KB read by the other page buffer circuit (e.g., 300B) is output in the input/output unit of x16. Thereby, it is possible to assist the x16 input/output mode of 2 KB in the multi-bit flash memory device. However, in the row address coding scheme, it may be difficult to assist the x16 input/output mode with 2 KB. In this case, in order to make the row address coding scheme assist the x16 input/output mode with 2 KB of data, it may be necessary to transform a page size from 1 KB into 2 KB. That is, each page buffer circuit may have to be altered or modified along with the architecture of the mat so as to read and program 2 KB page data.

Flash memory devices are a category of nonvolatile memories capable of keeping data stored therein even without power supply. With a rapid increase in the use of mobile devices such as cellular phones, personal digital assistants (PDA), digital cameras, portable gaming consoles, and MP3, the flash memory devices are increasingly being used for data storage as well as code storage purposes in such devices. Furthermore, the flash memory devices may be also utilized in home applications such as high-definition TVs, digital versatile disks (DVDs), routers, and global positioning systems (GPSs).

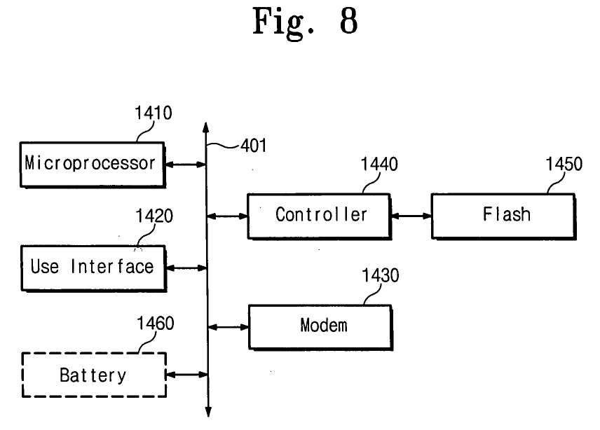

FIG. 8 is a block diagram showing a schematic computing system including a memory controller and a flash memory device according to an exemplary disclosed embodiment. In an exemplary embodiment, the computing system includes a microprocessor 1410, a use interface 1420, a modem 1430 such as a baseband chipset, a memory controller 1440, and a flash memory device 1450. The flash memory device 1450 may be configured as that shown FIG. 6. In the flash memory device 1450, N-bit data (N is a positive integer) to be processed by the processing unit 1410 is stored through the microprocessor 1410. In addition, if the computing system shown in FIG. 8 is a mobile apparatus, it may further comprise of a battery 1460 for supplying power thereto. Although not shown in FIG. 8, the computing system may be further equipped with an application chipset, a camera image processor (e.g., CMOS image sensor; CIS), a mobile DRAM, etc.

The above described flash memory device employing a flexible addressing scheme may be used in any semiconductor device application. As described above, it may be possible to flexibly determine an address coding scheme of the multi-bit flash memory device in accordance with operational conditions (e.g., the number of error bits correctable by ECC operation, input/output bit structure, page size, and so on) of the flash memory device. By using a flexible addressing scheme based on operational requirements, desirable features of both, a row address coding scheme and a column address scheme, may be used based on the specific operating conditions of the flash memory device.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A flash memory device comprising:
a flash memory cell array which includes a plurality of memory cells arranged in rows and columns;
reading and programming circuitry configured to read data from and program data into the memory cells of the flash memory cell array; and
a control logic block configured to regulate the reading and programming circuitry in accordance with a selected one of plural address coding schemes.

2. The flash memory device as set forth in claim 1, wherein each memory cell stores N-bit data, wherein N is an integer equal to or greater than 2.

3. The flash memory device as set forth in claim 2, wherein the plural address coding schemes includes a row address coding scheme in which two page addresses are assigned to a memory cell, and a column address coding scheme in which two column addresses are assigned to a memory cell.

4. The flash memory device as set forth in claim 1, wherein the one of the plural address coding schemes is selected in accordance with information provided from an external system.

5. The flash memory device as set forth in claim 1, wherein the one of the plural address coding schemes is selected in accordance information programmed in the flash memory device.

6. A flash memory device comprising:
a flash memory cell array including a plurality of memory cells, each of memory cells storing N-bit data, where N is an integer of 2 or more;
reading and programming circuitry configured to read data from and program data into the memory cells of the flash memory cell array;
a mode register configured to store information for selecting one of plural address coding schemes, and to generate a flag signal in accordance with the stored information; and
a control logic block configured to regulate the reading and programming circuitry in accordance with in response to the flag signal.

7. The flash memory device as set forth in claim 6, wherein the mode register is configured to store information provided from an external system.

8. The flash memory device as set forth in claim 6, wherein the mode register comprises a fuse circuit in which the information is programmed.

9. The flash memory device as set forth in claim 6, wherein the plural address coding schemes includes a row address coding scheme in which two page addresses are assigned to a memory cell, and a column address coding scheme in which two column addresses are assigned to a memory cell.

10. The flash memory device as set forth in claim 6, wherein the memory cell array comprises first and second mats, and wherein the reading/programming circuitry comprises:
a row selector configured to select the first and second mats;
first and second page buffer circuits, each configured to program and read data into and from a corresponding one of the mats under regulation by the control logic block;
first and second column selectors, each configured to select data from a corresponding one of the page buffer circuits under regulation by the control logic block in accordance with an input/output bit structure; and
a selection circuit configured to select one of the first and second column selectors under regulation of the control logic block.

11. The flash memory device as set forth in claim 6, wherein the control logic block comprises:
a first scheduler configured to control the reading and programming of the memory cell array in accordance with a row address coding scheme in response to the flag signal; and
a second scheduler configured to control the reading and programming of the memory cell array in accordance with a column address coding scheme in response to the flag signal.

12. The flash memory device as set forth in claim 6, wherein the memory cells are arranged in a NAND string structure.

13. A method for operating a flash memory device which includes a flash memory cell array of memory cells arranged in rows and columns, the method comprising selecting one of plural address coding schemes which are operatively available in the flash memory device, and conducting reading and programming operations in the memory cell array in accordance with the selected address coding scheme.

14. The method as set forth in claim 13, wherein the address coding scheme is selected in accordance with information provided from an external system.

15. The method as set forth in claim 13, wherein the address coding scheme is selected in accordance with information programmed in the flash memory device.

16. The method as set forth in claim 13, wherein the plural address coding schemes includes a row address coding scheme in which two page addresses are assigned to a memory cell, and a column address coding scheme in which two column addresses are assigned to a memory cell.

17. The method as set forth in claim 13, wherein the flash memory device is a multi-bit flash memory device.
